(19) United States
(12) Patent Application Publication
(10) Pub. No.: US 2023/0138570 A1
(43) Pub. Date: May 4, 2023

(54) GATE DRIVER PACKAGE FOR UNIFORM COUPLING TO DIFFERENTIAL SIGNAL BOND WIRE PAIRS

(71) Applicant: TEXAS INSTRUMENTS INCORPORATED, Dallas, TX (US)

(72) Inventors: Thomas Dyer BONIFIELD, Dallas, TX (US); Sarvesh Jagdish BANG, San Jose, CA (US); Chittranjan Mohan GUPTA, Richardson, TX (US)

(21) Appl. No.: 17/515,295

(22) Filed: Oct. 29, 2021

(51) Int. Cl. H01L 23/495; H01L 23/00; H01L 25/00; H01L 25/18; H01L 25/065

(52) U.S. Cl. CPC H01L 23/49575; H01L 23/49537; H01L 24/48; H01L 24/49; H01L 25/50; H01L 25/18; H01L 25/0655; H01L 23/49513; H01L 24/73; H01L 2224/73265; H01L 2224/48137; H01L 2224/48245; H01L 2224/48175; H01L 2224/49176; H01L 2224/48101; H01L 2224/48108; H01L 2224/49177; H01L 2224/49171; H01L 2224/49113; H01L 23/49555; H01L 24/92; H01L 2224/92247

(57) ABSTRACT

In examples, a semiconductor package comprises a first driver die adapted to be coupled to a high-side switch of a power supply, the first driver die adapted to drive a gate of the high-side switch. The package also includes a second driver die adapted to be coupled to a low-side switch of the power supply, the second driver die adapted to drive a gate of the low-side switch. The package also includes a controller die positioned between the first and second driver dies and configured to control the first and second driver dies. The package also includes a pair of bond wires configured to provide a differential signal between the controller die and the first driver die, a vertical plane of a bond wire in the pair of bond wires and a vertical plane of a side surface of the first driver die having an angle therebetween ranging from 80 to 95 degrees.

### BACKGROUND

Semiconductor chips are often housed inside semiconductor packages that protect the chips from deleterious environmental influences, such as heat, moisture, and debris. A packaged chip communicates with electronic devices outside the package via conductive members, such as leads, that are exposed to surfaces of the package. Within the package, the chip may be electrically coupled to the conductive members using any suitable technique. One such technique is the flip-chip technique, in which the semiconductor chip (also called a “die”) is flipped so the device side of the chip (in which circuitry is formed) is facing downward. The device side is coupled to the conductive members using, e.g., solder bumps. Another technique is the wirebonding technique, in which the device side of the semiconductor chip is oriented upward and is coupled to the conductive members using bond wires.

### SUMMARY

In examples, a semiconductor package comprises a first driver die adapted to be coupled to a high-side switch of a power supply, the first driver die adapted to drive a gate of the high-side switch. The package also includes a second driver die adapted to be coupled to a low-side switch of the power supply, the second driver die adapted to drive a gate of the low-side switch. The package also includes a controller die positioned between the first and second driver dies and configured to control the first and second driver dies. The package also includes a pair of bond wires configured to provide a differential signal between the controller die and the first driver die, a vertical plane of a bond wire in the pair of bond wires and a vertical plane of a side surface of the first driver die having an angle therebetween ranging from 80 to 95 degrees.

### BRIEF DESCRIPTION OF THE DRAWINGS

For a detailed description of various examples, reference will now be made to the accompanying drawings in which:

FIG. 1 is a circuit schematic diagram of a gate driver semiconductor package and a switched mode power supply in accordance with various examples.

FIGS. 2A1, 3A, 4A, 5A, and 6A are top-down views of various examples of a gate driver semiconductor package.

FIGS. 2A2, 2A3, and 2A4 are profile cross-sectional and top-down views of vertical planes in accordance with various examples.

FIGS. 2B, 3B, 4B, 5B, and 6B are perspective views of various examples of a gate driver semiconductor package.

FIGS. 2C, 3C, 4C, 5C, and 6C are profile views of various examples of a gate driver semiconductor package.

FIG. 7 is a flow diagram of a method for manufacturing a gate driver semiconductor package, in accordance with various examples.

### DETAILED DESCRIPTION

Some power supplies are known as switch mode power supplies (SMPS). SMPS generally include a pair of high-voltage, high-current switches, such as power field effect transistors (FETs), that are switched on and off in an alternating fashion to control a switch node positioned between the switches. One of the switches, known as a high-side switch (or a high-side transistor or high-side FET), is coupled to a constant power source, and the other switch, known as a low-side switch (or a low-side transistor or low-side FET), is coupled to ground. Gate drivers are coupled to control terminals (e.g., gates) of the high-side and low-side switches to control the switching action. The gate drivers, in turn, may be controlled by a controller circuit.

In some implementations, the controller circuit and the gate drivers are included in a single semiconductor package. Within the package, the controller circuit and the gate drivers are at least partially electrically isolated from each other to minimize cross-coupling and signal noise therebetween. For instance, the controller circuit and each of the gate drivers may be coupled to a different ground plane. The controller circuit may be coupled to each of the gate drivers using pairs of bond wires that provide differential signals (e.g., control signals) between the controller circuit and the gate drivers.

Despite efforts at electrical isolation, during operation, the high voltages and rapid switching action experienced by one or both of the gate drivers introduces parasitic capacitances and cross-coupling into the package. For example, the rapid, high-voltage switching action of a first gate driver may generate an electric field that cross-couples to a pair of bond wires connecting the controller circuit to a second gate driver. Because the pair of bond wires carries differential signals, any common-mode coupling effects are experienced equally by the pair of bond wires and are not reflected in the differential signal carried by the two bond wires. However, the geometry of the package significantly impacts the manner in which cross-coupling effects are experienced by each bond wire in a pair of bond wires, and this consistently results in asymmetric cross-coupling with the individual bond wires in each pair of bond wires. As a result, the differential signal between the pair of bond wires is altered, causing flawed operation of the gate driver to which the pair of bond wires connects.

This description provides various examples of a semiconductor package having an improved geometry that significantly mitigates the above-described asymmetric cross-coupling on a bond wire pair connecting a controller circuit to a gate driver. By using a package geometry that causes cross-coupling effects to be applied to bond wires in a pair of bond wires more equally, the negative impact on differential signals carried by the pair of bond wires is reduced, and gate driver operation is improved.

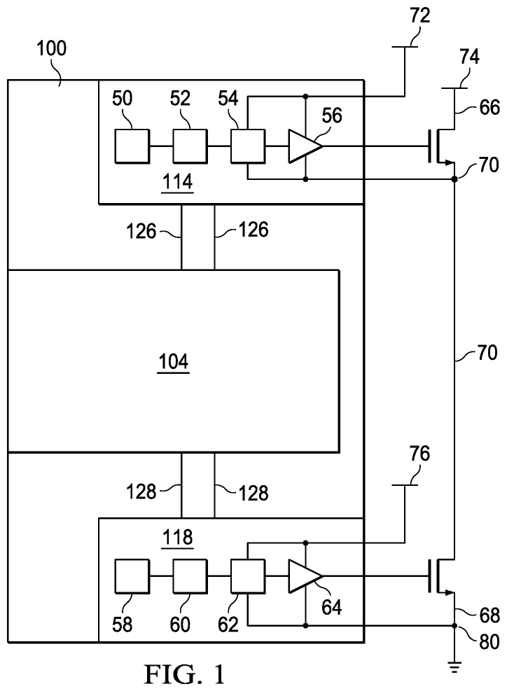

FIG. 1 is a circuit schematic diagram of a gate driver semiconductor package 100 and a switched mode power supply in accordance with various examples. The package 100 includes a controller die 104 and gate driver dies 114 and 118. The controller die 104 includes a controller circuit configured to control gate driver circuits formed in the gate driver dies 114 and 118. The gate driver circuit in the gate driver die 114 includes a differential amplifier 50, demodulation circuitry 52, under voltage lockout (UVLO) circuitry 54, and a driver amplifier 56. The gate driver circuit in the gate driver die 118 includes a differential amplifier 58, demodulation circuitry 60, UVLO circuitry 62, and a driver amplifier 64. The UVLO circuitry 54 and the driver amplifier 56 are adapted to be coupled to and powered by a power source 72. The UVLO circuitry 62 and the driver amplifier 64 are adapted to be coupled to and powered by a power source 76, and are further adapted to be coupled to ground 80. The package 100 is adapted to be coupled to a switched mode power supply (SMPS) that includes a high-side switch (e.g., a power field effect transistor (FET)) 66 and a low-side switch (e.g., a power FET) 68. The high-side switch 66 and the low-side switch 68 are coupled to each other at a switching node 70. For example, a source of the high-side switch 66 and a drain of the low-side switch 68 are coupled to each other at the switching node 70. The high-side switch 66 (e.g., a drain of the high-side switch 66) is adapted to be coupled to a power source 74. The low-side switch 68 (e.g., a source of the low-side switch 68) is adapted to be coupled to ground. The controller die 104 is coupled to the gate driver die 114 by way of a pair of bond wires 126. Similarly, the controller die 104 is coupled to the gate driver die 118 by way of a pair of bond wires 128. The controller die 104, the gate driver die 114, and the gate driver die 118 are at least partially electrically isolated from each other. For example, the controller die 104, the gate driver die 114, and the gate driver die 118 may be coupled to separate ground planes.

In operation, the controller die 104 controls the gate driver dies 114, 118 to drive the switches 66, 68, respectively, thereby operating the SMPS. A control signal provided by the controller die 104 is carried to the gate driver die 114 as a differential signal via the pair of bond wires 126. The control signal is processed by the differential amplifier 50, which may apply a common mode rejection to the control signal, for example in a ratio ranging from 2 to 50. The demodulation circuitry 52 may demodulate the control signal. The UVLO circuitry 54 may turn off some or all of the circuitry of the differential gate driver die 114 responsive to the power supplied by the power source 72 dropping below a threshold level that may be programmed into the UVLO circuitry 54. The driver amplifier 56 drives a control terminal (e.g., the gate) of the high-side switch 66 based on the demodulated, amplified signal. The differential amplifier 58, demodulator circuitry 60, UVLO circuitry 62, and driver amplifier 64 operate similarly to the differential amplifier 50, demodulation circuitry 52, UVLO circuitry 54, and driver amplifier 56, respectively.

As described above, the controller die 104 and the gate driver dies 114, 118 may be coupled to and operate in separate ground planes. For example, the gate driver die 118 is coupled to ground 80, whereas the gate driver die 114 (and, more specifically, the UVLO circuitry 54 and driver amplifier 56) is coupled to the switching node 70. The controller die 104 is coupled to a third ground connection that is electrically separated from the ground 80 and the switching node 70. Because the gate driver die 114 is coupled directly to the switching node 70, and because the switching node 70 experiences rapid and large voltage fluctuations as a result of the switching action of the SMPS, the gate driver die 114 has the potential to cross-couple with the pair of bond wires 128 and to distort the differential signal carried by the pair of bond wires 128. However, in examples, the bond wires in the pair of bond wires 128 are approximately parallel to each other, and they lie in vertical planes that are approximately orthogonal to a vertical plane of a side surface of the gate driver die 118. As a result, the electric field generated by the gate driver die 114 affects the bond wires in the pair of bond wires 128 equally or approximately equally, and the differential signal between the bond wires is unaffected or approximately unaffected. The principle that preserves the integrity of the differential signal in this manner is that the more the geometry of the package 100 is designed to equalize coupling effects from the gate driver die 114 on the two bond wires in the pair of bond wires 128, the better the integrity of the differential signal will be preserved. The same rationale applies to the pair of bond wires 126. Further, the presence of the controller die 104 and, in examples, a controller die pad in between the gate driver dies 114, 118 reduces the coupling described above.

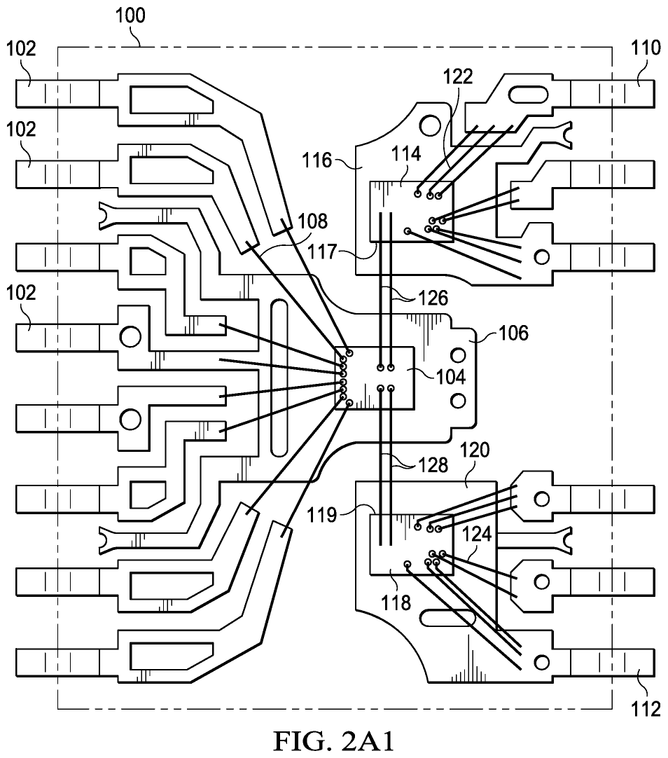

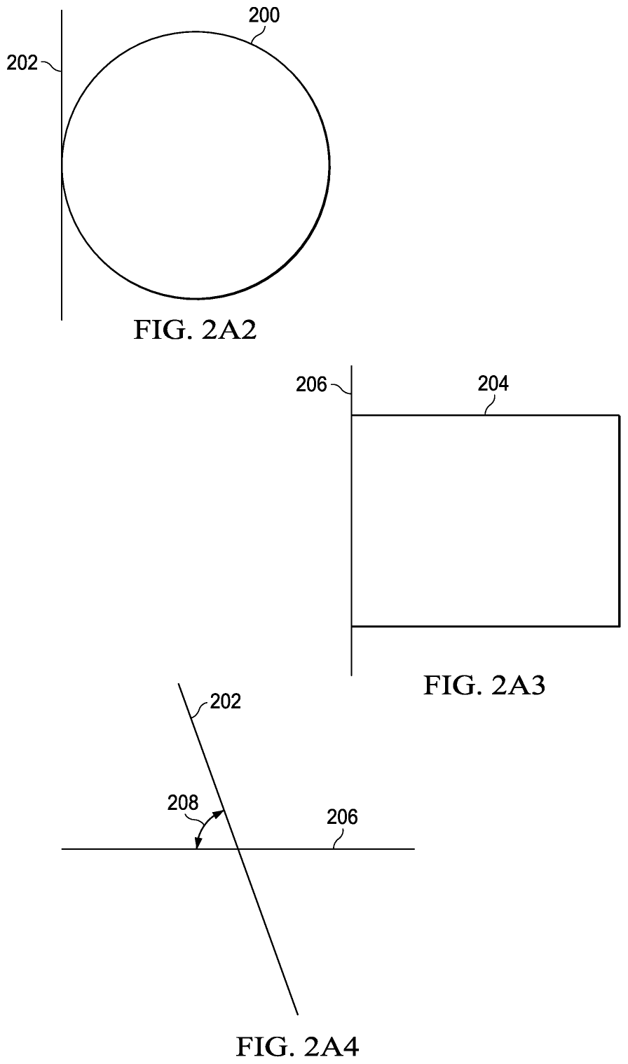

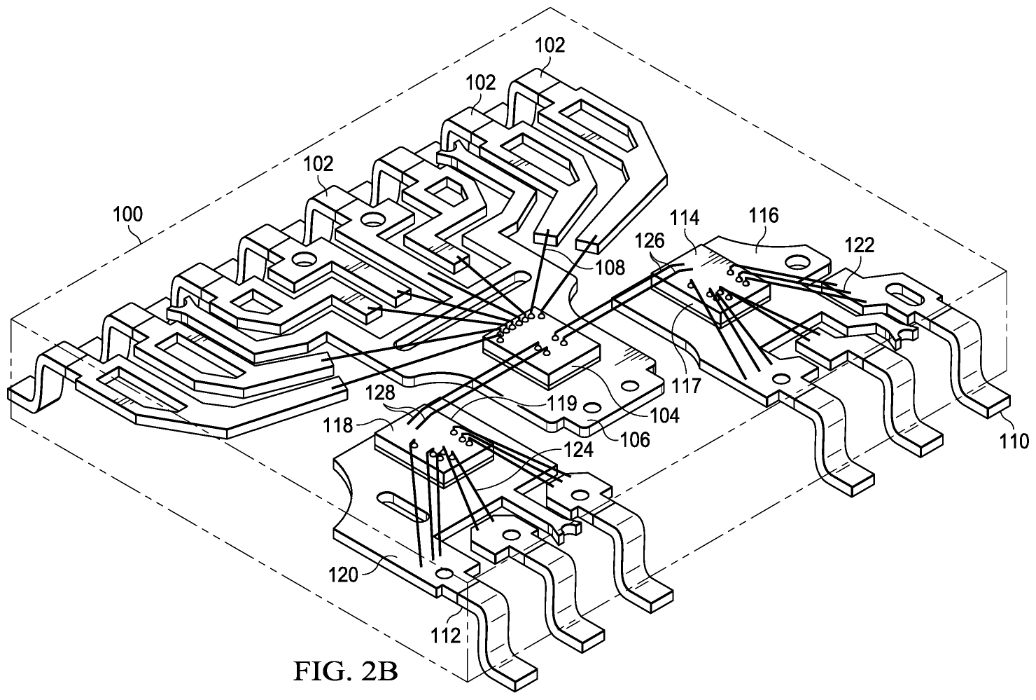

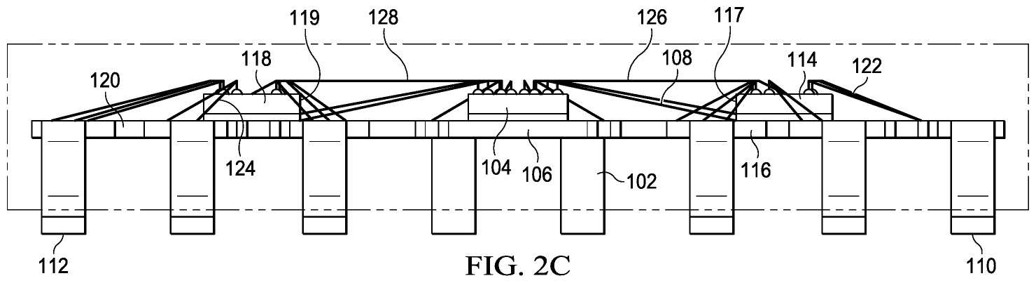

FIG. 2A1 is a top-down view of a gate driver semiconductor package 100, in accordance with various examples. The package 100 includes conductive terminals 102 (e.g., leads, such as gullwing style leads), conductive terminals 110 (e.g., leads, such as gullwing style leads), and conductive terminals 112 (e.g., leads, such as gullwing style leads). The conductive terminals 102 are coupled to a controller die pad 106, and the controller die 104 is coupled to the controller die pad 106, for example by way of a die attach layer (not expressly shown). The conductive terminals 110 are coupled to a gate driver die pad 116, and the gate driver die 114 is coupled to the gate driver die pad 116, for example by way of a die attach layer (not expressly shown). The conductive terminals 112 are coupled to a gate driver die pad 120, and the gate driver die 118 is coupled to the gate driver die pad 120, for example by way of a die attach layer (not expressly shown). The controller die 104 is coupled to the gate driver die 114 by way of the pair of bond wires 126. The controller die 104 is coupled to the gate driver die 118 by way of the pair of bond wires 128. The top surface of the controller die 104 includes circuitry that performs the actions attributed herein to the controller die 104. The top surface of the gate driver die 114 includes circuitry that performs the actions attributed herein to the gate driver die 114. For example, the gate driver die 114 includes the circuitry represented in the gate driver die 114 in FIG. 1. The top surface of the gate driver die 118 includes circuitry that performs the actions attributed herein to the gate driver die 118. For example, the gate driver die 118 includes the circuitry represented in the gate driver die 118 in FIG. 1. Bond wires 122 couple the gate driver die 114 to the conductive terminals 110, and bond wires 124 couple the gate driver die 118 to the conductive terminals 112. Bond wires 108 couple conductive terminals 102 to the controller die 104.

As described above, the bond wires in the pair of bond wires 126 are approximately parallel to each other. If the pair of bond wires 126 were not parallel or at least approximately parallel to each other, the bond wires in the pair of bond wires 126 may be affected asymmetrically by the electric field produced by the gate driver die 118, thereby undesirably impacting the differential signal carried by the pair of bond wires 126. Similarly, the pair of bond wires 128 are approximately parallel to each other. If the pair of bond wires 128 were not parallel or at least approximately parallel to each other, the bond wires in the pair of bond wires 128 may be affected asymmetrically by the electric field produced by the gate driver die 114, thereby undesirably impacting the differential signal carried by the pair of bond wires 128.

In addition, as described above, the bond wires in the pair of bond wires 126 lie in vertical planes, each of which is orthogonal or at least approximately orthogonal to a vertical plane of a side surface 117 of the gate driver die 114. As used herein, the term “vertical plane” means a plane that is either a) oriented orthogonally with reference to a horizontal plane that coincides with the surface of the gate driver die 118 that is coupled to the bond wires 124, or b) oriented in a direction that is within 20 degrees of the orientation described in a). For example, if the aforementioned horizontal plane is the x-y plane of a three-dimensional Cartesian coordinate system, the vertical plane may be the x-z plane of the coordinate system, or the vertical plane may be within 10 degrees of the x-z plane in the direction of the x-y plane. A vertical plane associated with a bond wire refers to a vertical plane that coincides with an outermost point of an exterior surface of that bond wire. A vertical plane associated with a surface (e.g., side surface 117) of a die (e.g., gate driver die 114) refers to a vertical plane that coincides with an outermost point of that surface. FIG. 2A2 is a cross-sectional view of a bond wire 200 and a vertical plane 202 of the bond wire 200 that extends through an outermost point of the exterior of the bond wire 200, consistent with the description provided above. FIG. 2A3 is a cross-sectional view of a die 204 and a vertical plane 206 of the die 204 that extends through an outermost point of a surface of the die 204, consistent with the description provided above. FIG. 2A4 is a top-down view of the vertical planes 202 and 206 forming an angle 208 therebetween, as described in detail below.

If the pair of bond wires 126 were not at least approximately orthogonal in this manner, the bond wires in the pair of bond wires 126 might be affected asymmetrically by the electric field produced by the gate driver die 118, thereby negatively impacting the differential signal carried by the pair of bond wires 126. Similarly, as described above, the bond wires in the pair of bond wires 128 lie in vertical planes, each of which is orthogonal or at least approximately orthogonal to a vertical plane of a side surface 119 of the gate driver die 118. If the pair of bond wires 128 were not at least approximately orthogonal in this manner, the bond wires in the pair of bond wires 128 might be affected asymmetrically by the electric field produced by the gate driver die 114, thereby negatively impacting the differential signal carried by the pair of bond wires 128. Furthermore, the presence of the controller die 104 and the controller die pad 106 in between the gate driver dies 114, 118 blocks the coupling effects of the gate driver die 114 on the pair of bond wires 128 and the coupling effects of the gate driver die 118 on the pair of bond wires 126.

Various parameters of the structures within the package 100 affect the degree to which differential signals carried on the pairs of bond wires 126, 128 are impacted by coupling with gate driver dies 114, 118. The distance between each gate driver die 114, 118 and the opposing pair of bond wires 126, 128 affects the coupling to the pair of bond wires 126, 128. The distance between the gate driver die 114 and the pair of bond wires 128 (e.g., the points at which the pair of bond wires 128 couple to the controller die 104), or between the gate driver die 118 and the pair of bond wires 126 (e.g., the points at which the pair of bond wires 126 couple to the controller die 104), is critical to preventing excessive cross-coupling, and this distance (which is application-specific) may be achieved by, e.g., expanding a width of the controller die 104, expanding a width of the controller die pad 106, relocating the controller die 104 on the controller die pad 106, expanding the distance between the gate driver die pads 116, 120, relocating the gate driver dies 114, 118 on the gate driver die pads 116, 120, etc. Further, the degree to which a structure, such as the combination of the controller die 104 and the controller die pad 106, is positioned between the gate driver dies 114, 118 and the opposing pair of bond wires 126, 128 impacts the electric fields generated by, and coupling associated with, the gate driver dies 114, 118. For example, if the controller die pad 106 only partially enters the space that exists between the gate driver die pads 116, 120, the blocking of the electric field and coupling effects will be minimal, thereby negatively impacting the differential signal between the pair of bond wires 126 and the differential signal between the pair of bond wires 128. In contrast, if the controller die pad 106 is fully within the space that exists between the gate driver die pads 116, 120 such that no line that extends through the gate driver dies 114, 118 does not also extend through the controller die pad 106, the electric field is significantly blocked and coupling is mitigated. As described above, having a pair of bond wires 126 that are in vertical planes that intersect at an angle between 80 and 95 degrees with the vertical plane of the side surface 117 and having a pair of bond wires 128 that are in vertical planes that intersect at an angle between 80 and 95 degrees with the vertical plane of the side surface 119 results in minimal effect on the differential signals carried by these pairs of bond wires 126, 128. The optimal intersection angle, therefore, is 90 degrees. However, angles between 80 and 95 degrees can be used, albeit with greater coupling effect on the differential signals carried by the pairs of bond wires 126, 128, as described below.

FIG. 2B is a perspective view of the package 100 of FIG. 2A1, in accordance with various examples. FIG. 2C is a profile view of the package 100 of FIG. 2A1, in accordance with various examples.

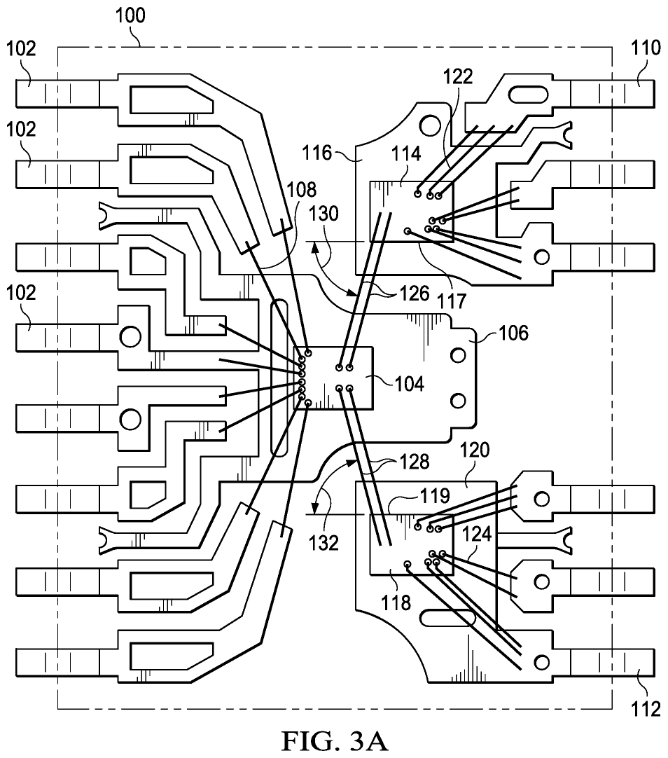

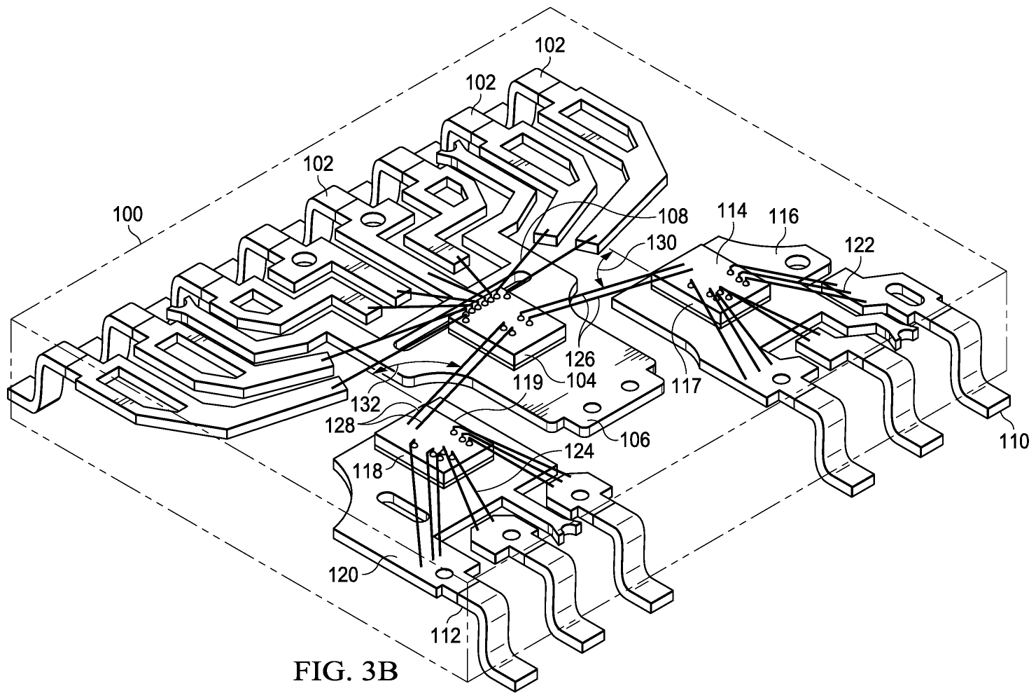

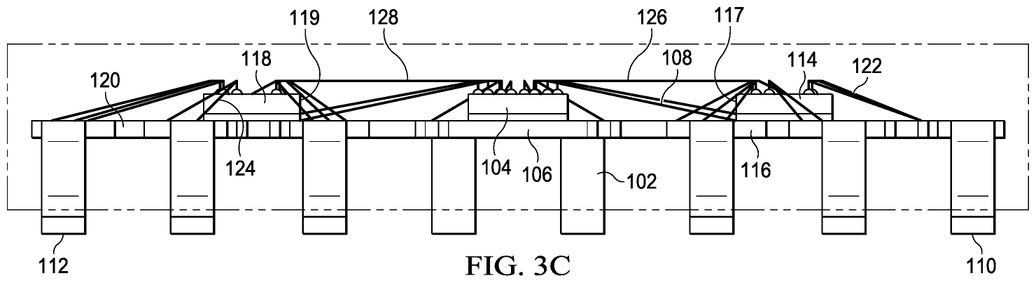

FIG. 3A is a top-down view of another example of the package 100. The package 100 of FIG. 3A includes the same structures as package 100 in FIG. 2A1, but with the controller die 104 shifted to the left relative to the position of the controller die 104 in FIG. 2A1. As a result, the pairs of bond wires 126, 128 are no longer in vertical planes that intersect the vertical planes of the side surfaces 117, 119 at approximately 90 degrees. Instead, the pairs of bond wires 126 are in vertical planes that intersect the vertical plane of the side surface 117 at an angle 130, and the pairs of bond wires 128 are in vertical planes that intersect the vertical plane of the side surface 119 at an angle 132. The angles 130, 132 do not drop below 80 degrees or rise above 95 degrees, as such an angle would result in an unacceptable degree of asymmetrical coupling between the bond wires in the pair of bond wires 126, 128. FIG. 3B is a perspective view of the example package 100 of FIG. 3A, and FIG. 3C is a profile view of the example package 100 of FIG. 3A.

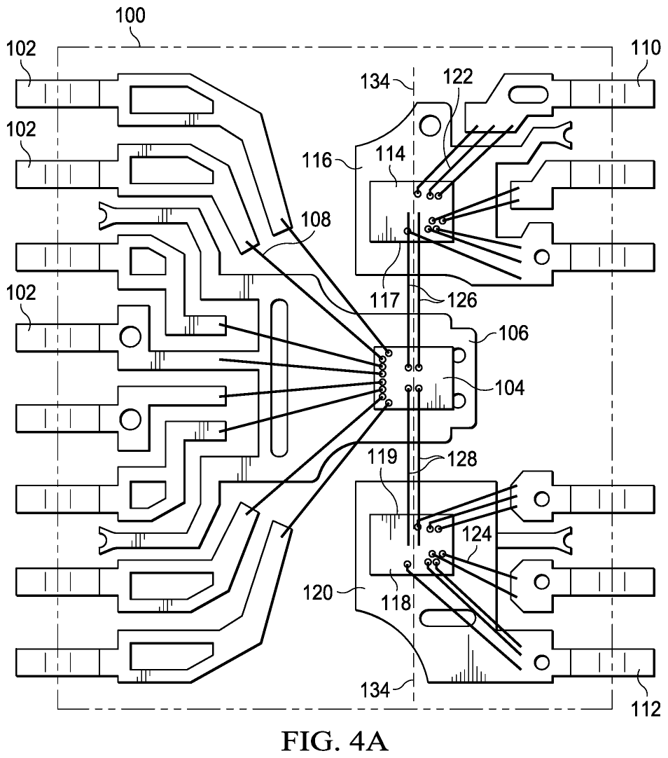

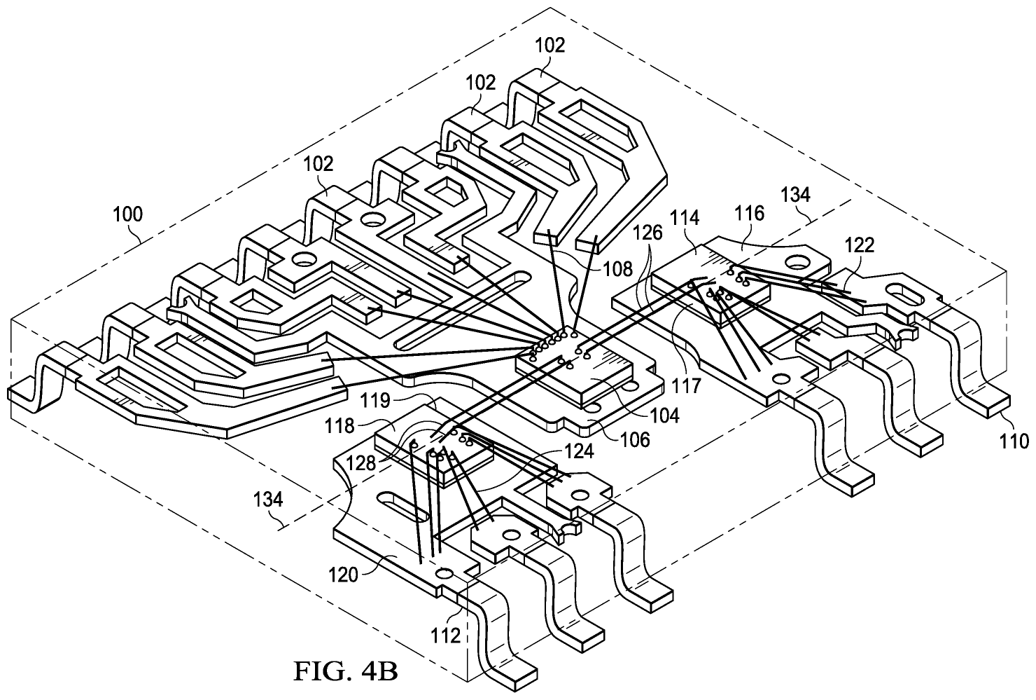

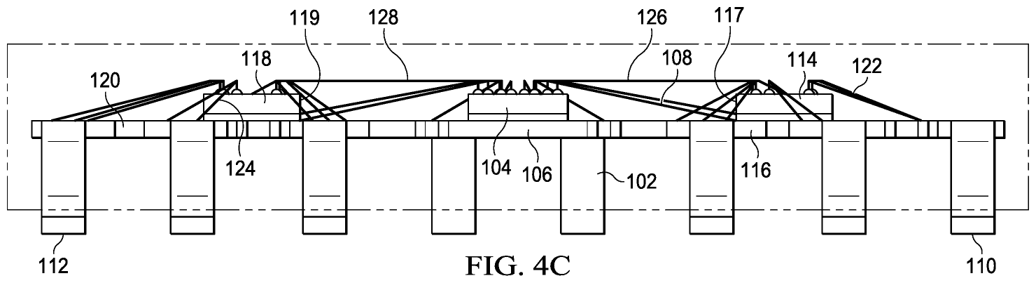

FIG. 4A is a top-down view of another example of the package 100. The package 100 of FIG. 4A includes the same structures as package 100 of FIG. 2A1, but with the controller die 104 shifted to the right relative to the position of the controller die 104 in FIG. 2A1. As a result, the pairs of bond wires 126, 128 are in vertical planes that intersect the vertical planes of the side surfaces 117, 119 at approximately 90 degrees or between 80 and 95 degrees. In addition, each bond wire in the pair of bond wires 126 is approximately equidistant from a centerline 134 of the gate driver die 114 that bisects the side surface 117. Similarly, each bond wire in the pair of bond wires 128 is approximately equidistant from the centerline 134 of the gate driver die 118 that bisects the side surface 119. In examples, the gate driver dies 114, 118 do not share a common centerline, and their respective centerlines may be offset from each other. In such a case, the bond wires in the pair of bond wires 126 will be equidistant from the centerline of the gate driver die 114, and the bond wires in the pair of bond wires 128 will be equidistant from the centerline of the gate driver die 118. By establishing equidistance of the bond wires in each pair of bond wires 126, 128 from the centerline 134 (or respective, separate centerlines as described above), and further by maintaining a 90 degree angle between the vertical planes of the bond wires in each pair of bond wires 126, 128 and the vertical planes of respective side surfaces 117, 119 as described above, the symmetry of the bond wires in each pair of bond wires 126, 128 is increased, and disparate coupling among the bond wires in each pair of bond wires 126, 128 is decreased. In this way, coupling effects on the differential signals between the bond wires in each pair of bond wires 126, 128 are minimized, and the gate driver die circuits operate as intended.

In some examples, the distance between the centerline 134 and respective bond wires of a pair of bond wires 126, 128 is not equidistant, but instead is adjusted (e.g., during manufacture) using a tuning process to account for variations in design of the corresponding gate driver die 114, 118. For example, the specific circuit layout of a particular gate driver die 114, 118 may be such that spacing one bond wire of a pair of bond wires 126, 128 a distance x from the centerline 134 and spacing the other bond wire of the pair of bond wires 126, 128 a distance y from the centerline 134 may produce optimal mitigation of coupling effects and may maximize effective symmetry, even though the spacing of the bond wires in the pair of bond wires 126, 128 may not be physically symmetrical with respect to the centerline 134. Such variations are contemplated and included in the scope of this disclosure. FIG. 4B is a perspective view of the structure of FIG. 4A, and FIG. 4C is a profile view of the structure of FIG. 4A.

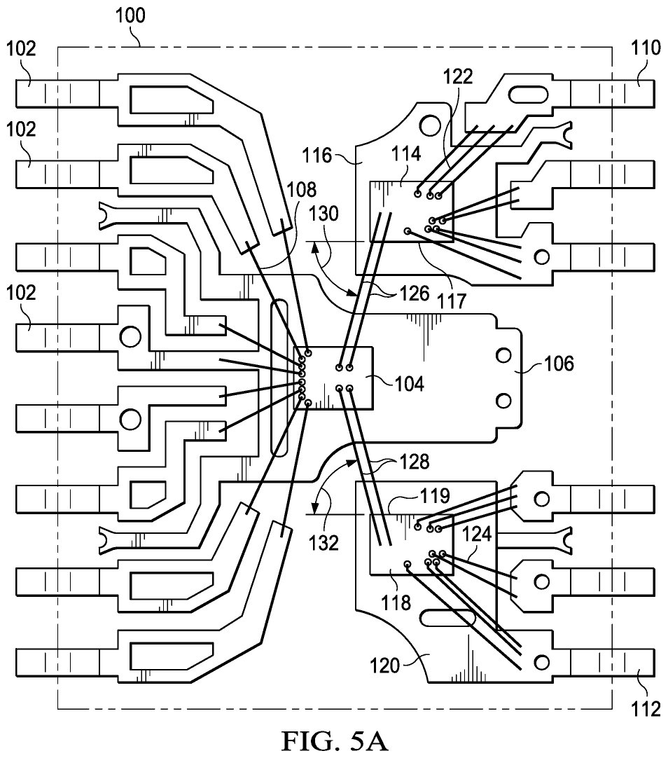

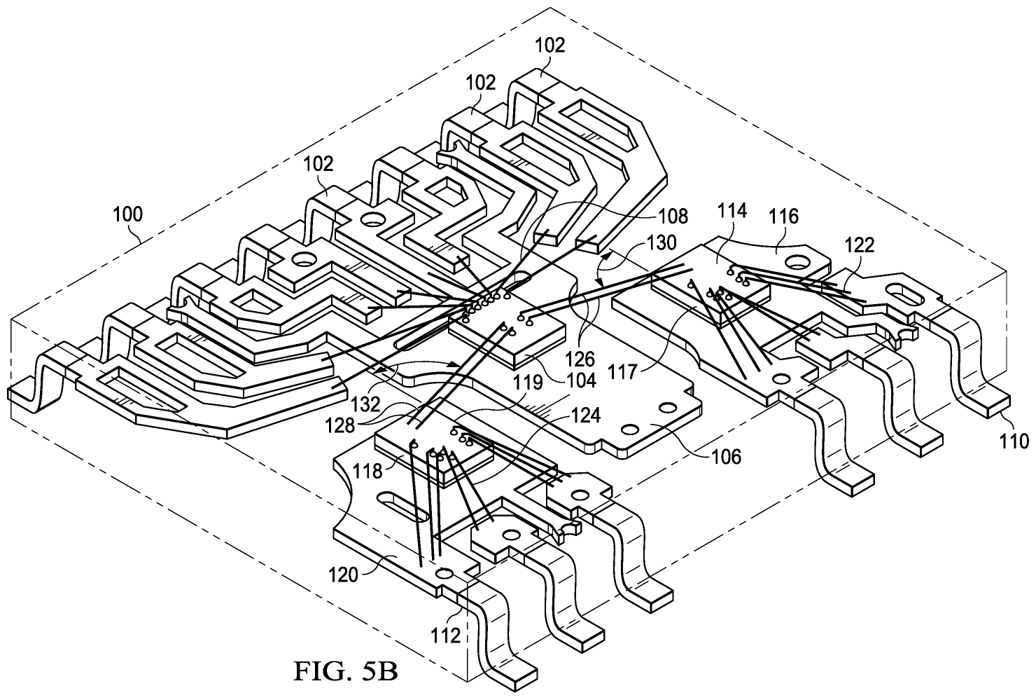

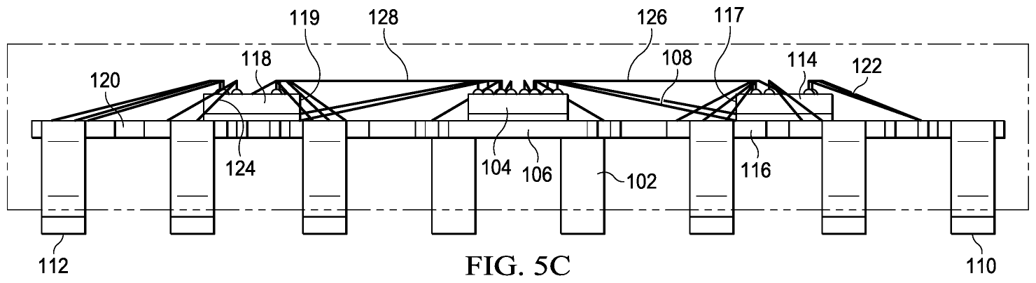

FIG. 5A is a top-down view of another example of the package 100. The package 100 of FIG. 5A includes the same structures as package 100 of FIG. 3A, but with the controller die pad 106 extended to the right so that all lines that pass through both the gate driver dies 114, 118 also pass through the controller die pad 106. The presence of the controller die pad 106 in all areas co-linear with the gate driver dies 114, 118 significantly mitigates the undesirable effects of coupling, described above. FIG. 5B is a perspective view of the package 100 of FIG. 5A, and FIG. 5C is a profile view of the package 100 of FIG. 5A.

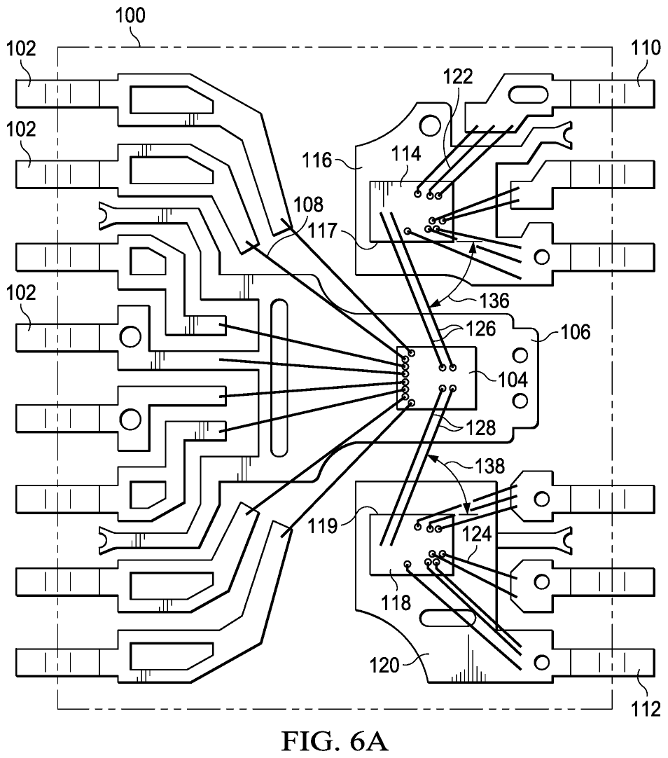

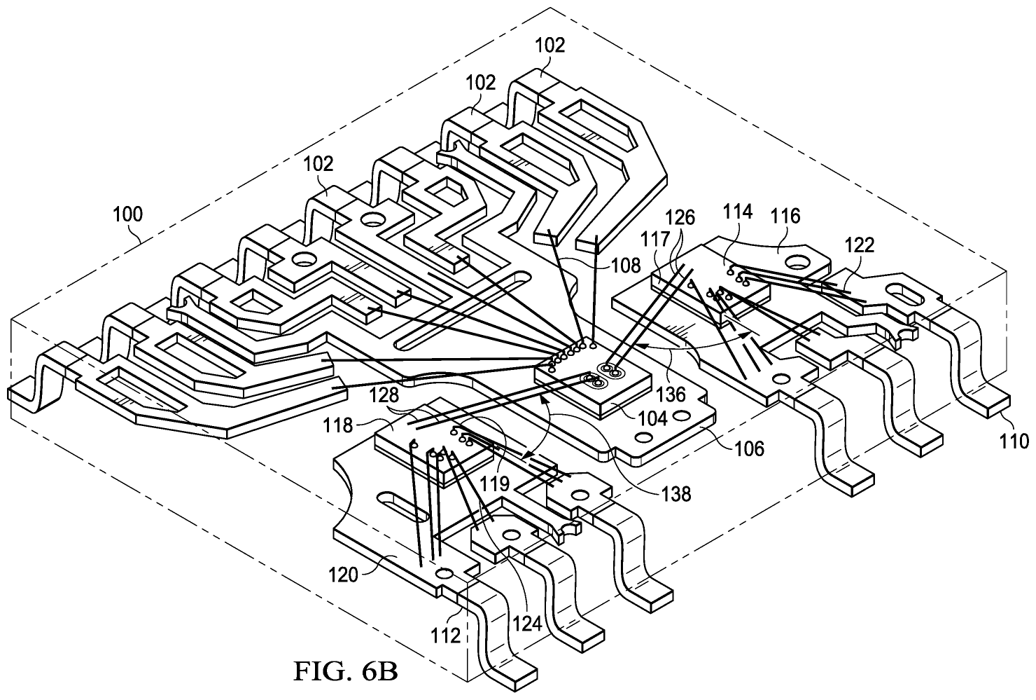

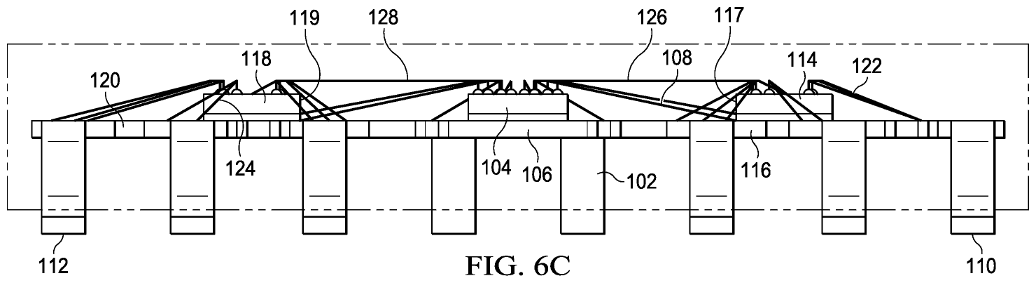

FIG. 6A is a top-down view of another example of the package 100. The package 100 of FIG. 6A includes the same structures as package 100 of FIG. 2A1, but with the controller die pad 106 extended to the right as in FIG. 5A, and with the controller die 104 shifted to the right as the controller die 104 is shifted to the left in FIG. 3A. As shown in FIG. 6A, the bond wires in the pair of bond wires 126 are in a vertical plane that intersects the vertical plane of the side surface 117 at an angle 136. Similarly, the bond wires in the pair of bond wires 128 are in a vertical plane that intersects the vertical plane of the side surface 119 at an angle 138. The angles 136, 138 range from 80 degrees to 95 degrees, with an angle 136, 138 outside of this range being disadvantageous because it results in an unacceptable degree of disparate coupling effects on the bond wires in a corresponding pair of bond wires 126, 128. The extension of the controller die pad 106 to the right as shown in FIG. 6A provides the same advantages as described above with reference to FIG. 5A. FIG. 6B is a perspective view of the package 100 of FIG. 6A, and FIG. 6C is a profile view of the package 100 shown in FIG. 6A.

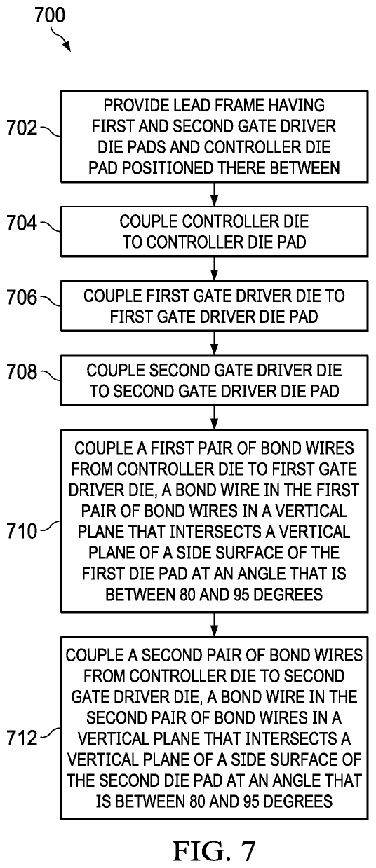

FIG. 7 is a flow diagram of a method 700 for manufacturing a gate driver semiconductor package, such as the various examples of the package 100 described herein, in accordance with various examples. The method 700 includes providing a lead frame having first and second gate driver die pads and a controller die pad positioned between the first and second gate driver die pads (702). The method 700 includes coupling a controller die to the controller die pad (704), for example, using a die attach layer. The method 700 includes coupling a first gate driver die to the first gate driver die pad (706), for example, using a die attach layer. The method 700 includes coupling a second gate driver die to the second gate driver die pad (708), for example, using a die attach layer. The method 700 includes coupling a first pair of bond wires from the controller die to the first gate driver die, where a bond wire in the first pair of bond wires is in a vertical plane that intersects a vertical plane of a side surface of the first die pad at an angle that is between 80 and 95 degrees (710). The method 700 includes coupling a second pair of bond wires from the controller die to the second gate driver die, where a bond wire in the second pair of bond wires is in a vertical plane that intersects a vertical plane of a side surface of the second die pad at an angle that is between 80 and 95 degrees.

Experimental data supports the superiority of the examples described herein relative to other solutions, and in particular the criticality of the above-described 80-95 degree ranges for angles 130, 132, 136, and 138. In an experiment, cross-coupling measurements were performed for an example described herein (with angles 130, 132, 136, and 138 in the 80-95 degree range) and were compared to cross-coupling measurements for two other solutions. For the example described herein, a first pair of bond wires coupled to a controller die and to a gate driver die had couplings of 5.72 femto Farads (fF) and 6.31 fF on the individual bond wires of that first pair. Thus, the differential coupling was 0.59 fF. A second pair of bond wires coupled to the controller die and to another gate driver die had couplings of 5.84 fF and 6.43 fF on the individual bond wires of that second pair of bond wires. Thus, the differential coupling was 0.59 fF. For a prior solution, a first pair of bond wires coupled to a controller die and to a gate driver die had couplings of 2.28 femto Farads (fF) and 3.67 fF on the individual bond wires of that first pair. Thus, the differential coupling was 1.39 fF. A second pair of bond wires coupled to the controller die and to another gate driver die had couplings of 2.39 fF and 3.86 fF on the individual bond wires of that second pair of bond wires. Thus, the differential coupling was 1.47 fF. For another prior solution, a first pair of bond wires coupled to a controller die and to a gate driver die had couplings of 6.66 femto Farads (fF) and 13.67 fF on the individual bond wires of that first pair. Thus, the differential coupling was 7.01 fF. A second pair of bond wires coupled to the controller die and to another gate driver die had couplings of 7.17 fF and 14.69 fF on the individual bond wires of that second pair of bond wires. Thus, the differential coupling was 7.52 fF. Thus, in this experiment, a prior solution produced differential couplings that were over 12 times larger than the differential couplings produced by an example described herein.

The term “couple” is used throughout the specification. The term may cover connections, communications, or signal paths that enable a functional relationship consistent with this description. For example, if device A generates a signal to control device B to perform an action, in a first example device A is coupled to device B, or in a second example device A is coupled to device B through intervening component C if intervening component C does not substantially alter the functional relationship between device A and device B such that device B is controlled by device A via the control signal generated by device A.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

Uses of the term “ground” in the foregoing description include a chassis ground, an Earth ground, a floating ground, a virtual ground, a digital ground, a common ground, and/or any other form of ground connection applicable to, or suitable for, the teachings of this description. Unless otherwise stated, “about,” “approximately,” or “substantially” preceding a value means+/−10 percent of the stated value. Modifications are possible in the described examples, and other examples are possible within the scope of the claims.

What is claimed is:

1. A semiconductor package, comprising:
a first driver die adapted to be coupled to a high-side switch of a power supply, the first driver die adapted to drive a gate of the high-side switch;
a second driver die adapted to be coupled to a low-side switch of the power supply, the second driver die adapted to drive a gate of the low-side switch;
a controller die positioned between the first and second driver dies and configured to control the first and second driver dies; and
a pair of bond wires configured to provide a differential signal between the controller die and the first driver die, a vertical plane of a bond wire in the pair of bond wires and a vertical plane of a side surface of the first driver die having an angle therebetween ranging from 80 to 95 degrees.

2. The semiconductor package of claim 1, wherein the first driver die, the second driver die, and the controller die have separate ground planes.

3. The semiconductor package of claim 1, wherein a ground plane of the first driver die is coupled to a switching node of the power supply, the switching node between the high-side and low-side switches.

4. The semiconductor package of claim 1, wherein bond wires in the pair of bond wires are approximately parallel to each other.

5. The semiconductor package of claim 1, wherein the side surface of the first driver die faces the second driver die and the controller die.

6. The semiconductor package of claim 1, wherein the angle is 90 degrees.

7. The semiconductor package of claim 1, wherein a centerline of the first driver die bisects the side surface of the first driver die, and wherein the pair of bond wires are equidistant from the centerline.

8. The semiconductor package of claim 1, wherein the first driver die includes a differential amplifier that is configured to apply common mode rejection to a signal received via the pair of bond wires.

9. The semiconductor package of claim 8, wherein the common mode rejection has a ratio ranging from 2 to 50.

10. A semiconductor package, comprising:
a first driver die adapted to be coupled to a high-side switch of a power supply, the first driver die adapted to drive a gate of the high-side switch;
a second driver die adapted to be coupled to a low-side switch of the power supply, the second driver die adapted to drive a gate of the low-side switch;
a controller die configured to control the first and second driver dies, a plane extending through the first driver die, the second driver die, and the controller die;
a first pair of bond wires configured to provide a first differential signal between the controller die and the first driver die, a vertical plane of a bond wire in the first pair of bond wires orthogonal to a vertical plane of a side surface of the first driver die; and
a second pair of bond wires configured to provide a second differential signal between the controller die and the second driver die, a vertical plane of a bond wire in the second pair of bond wires orthogonal to a vertical plane of a side surface of the second driver die, the side surfaces of the first and second driver dies facing each other.

11. The semiconductor package of claim 10, wherein the first driver die, the second driver die, and the controller die have separate ground planes.

12. The semiconductor package of claim 10, wherein a ground plane of the first driver die is coupled to a switching node of the power supply, the switching node between the high-side and low-side switches.

13. The semiconductor package of claim 10, wherein bond wires in the first pair of bond wires are approximately parallel to each other.

14. The semiconductor package of claim 10, wherein a centerline of the first driver die bisects the side surface of the first driver die, and wherein the first pair of bond wires are equidistant from the centerline.

15. The semiconductor package of claim 10, wherein the first driver die includes a differential amplifier that is configured to apply common mode rejection to a signal received via the first pair of bond wires.

16. The semiconductor package of claim 15, wherein the common mode rejection has a ratio ranging from 2 to 50.

17. A semiconductor package, comprising:
a first die pad having a first driver die positioned thereupon, the first driver die configured to drive a high-side switch of a power supply;
a second die pad having a second driver die positioned thereupon, the second driver die configured to drive a low-side switch of the power supply;
a controller die pad having a controller die positioned thereupon, the controller die configured to control the first and second driver dies, the controller die pad positioned between the first and second driver dies such that no line extends through both the first and second driver dies without also extending through the controller die pad; and
a pair of bond wires approximately in parallel with each other, a bond wire in the pair of bond wires in a vertical plane that intersects a vertical plane of a side surface of the first die pad at an angle that is between 80 and 95 degrees.

18. The semiconductor package of claim 17, wherein the first driver die, the second driver die, and the controller die have separate ground planes.

19. The semiconductor package of claim 17, wherein a ground plane of the first driver die is coupled to a switching node of the power supply, the switching node between the high-side and low-side switches.

20. The semiconductor package of claim 17, wherein the side surface of the first die pad faces the second die pad and the controller die pad.

21. The semiconductor package of claim 17, wherein the first driver die includes a differential amplifier that is configured to apply common mode rejection to a signal received via the pair of bond wires.

22. The semiconductor package of claim 21, wherein the common mode rejection has a ratio ranging from 2 to 50.

23. A method for manufacturing a semiconductor package, comprising:
providing a lead frame having first and second gate driver die pads and a controller die pad positioned between the first and second gate driver die pads;
coupling a controller die to the controller die pad;
coupling a first gate driver die to the first gate driver die pad;
coupling a second gate driver die to the second gate driver die pad; and
coupling a pair of bond wires from the controller die to the first gate driver die, a bond wire in the pair of bond wires in a vertical plane that intersects a vertical plane of a side surface of the first gate driver die pad at an angle that is approximately 90 degrees.
